(19) United States
(12) Patent Application Publication
(10) Pub. No.: US 2012/0187447 A1
(43) Pub. Date: Jul. 26, 2012

(54) Part having a First and a Second Substrate and Method for the Production Thereof

(75) Inventors: Angela Eberhardt, Augsburg (DE); Ulrike Beer, Meitingen (DE); Joachim Wirth-Schön, Gunzburg (DE); Ewald Pösl, Kissing (DE)

(73) Assignee: Osram Opto Semiconductors GMBH, Regensburg (DE)

(21) Appl. No.: 13/318,343

(22) PCT Filed: Apr. 28, 2010
(86) PCT No.: PCT/DE10/00491

§ 371 Date: Dec. 19, 2011

(30) Foreign Application Priority Data
Apr. 30, 2009 (DE) 10 2009 019 518.1
Aug. 6, 2009 (DE) 10 2009 036 395.5

(51) Int. Cl. H01L 33/48

(52) U.S. Cl. 257/99; 438/26; 257/E33.058

(57) ABSTRACT

A unit is provided which comprises a first substrate (1) and a second substrate (2). At least one optoelectronic component (4) containing at least one organic material is arranged on the first substrate (1). The first substrate (1) and the second substrate (2) are arranged relative to one another such that the optoelectronic component (4) is arranged between the first substrate (1) and the second substrate (2). In addition, a bonding material (3) is arranged between the first substrate (1) and the second substrate (2), which material encloses the optoelectronic component (4) and bonds the first and second substrates (1, 2) together mechanically. The bonding material (3) contains silver oxide in a proportion of more than 0 wt. % and less than 100 wt. %, preferably between 5 wt. % and 80 wt. % inclusive, ideally between 10 wt. % and 70 wt. % inclusive. The bonding material (3) may further contain at least one filler (5), which changes, preferably reduces, the coefficient of thermal expansion of the bonding material (3). In addition, a method of producing such a unit is provided.

The present patent application claims priority from German patent applications 10 2009 019 518.1 and 10 2009 036 395.5, the disclosure content of which is hereby included by reference.

The present invention relates to a unit having a first substrate and a second substrate. The invention relates to a method of producing such a unit.

Organic, light-emitting diodes (OLED) which are arranged between two substrates may be sealed by means of an adhesive layer. The adhesive layer is then located between the two substrates. The adhesive is cured using UV radiation, for example. Since the adhesive layer is not completely oxygen- and water vapour-tight, these gases may diffuse over time through the adhesive layer into the OLED. Since the OLED is not oxygen- and hydrogen-resistant, this may lead to damage to the OLED and to a reduction in the service life of the OLED.

In order to increase the service life of the OLED, it is possible to form a cavity in one of the substrates and introduce a getter into the cavity.

A getter is in particular a chemically reactive material, which serves to maintain a vacuum for long as possible. At the surface of a getter, gas molecules enter into a direct chemical bond with the atoms of the getter material or the gas molecules are retained by sorption. In this way gas molecules are “captured”.

However a cavity introduced into one of the substrates and a getter introduced into the cavity disadvantageously increase the costs of and manufacturing effort required for such units.

A device which comprises two substrates and an OLED arranged therebetween is known for example from U.S. Pat. No. 6,998,776 B2.

It is the object of the present invention to provide an improved unit which protects an organic optoelectronic component from environmental influences and at the same is cheap and simple to produce.

These objects are achieved inter alia by a unit having the features of claim 1 and a method for the production thereof having the features of claim 13. Advantageous embodiments and preferred further developments of the unit and of the method for the production thereof are the subject matter of the dependent claims.

In one embodiment of the unit a first substrate and a second substrate are provided, at least one optoelectronic component being arranged on the first substrate, which component contains at least one organic material.

The first substrate and the second substrate are preferably arranged relative to one another such that the optoelectronic component is arranged between the first substrate and the second substrate.

In a further embodiment a bonding material is arranged between the first substrate and the second substrate, which material encloses the optoelectronic component and bonds the first and second substrates together mechanically. The bonding material preferably surrounds the optoelectronic component. Particularly preferably, the bonding material completely surrounds the optoelectronic component. The bonding material encloses the optoelectronic component in the manner of a frame, for example.

The bonding material preferably contains silver oxide in a proportion of more than 0 wt. % and less than 100 wt. %, preferably between 5 wt. % and 80 wt. % inclusive, ideally between 10 wt. % and 70 wt. % inclusive. In particular, the silver oxide does not stem from contamination, but rather is introduced deliberately into the bonding material as an ingredient or doping.

The bonding material preferably includes at least one filler, which changes, preferably reduces, the coefficient of thermal expansion of the bonding material.

In a particularly preferred embodiment, the unit comprises a first substrate and a second substrate, at least one optoelectronic component being arranged on the first substrate, which component contains at least one organic material. The first substrate and the second substrate are arranged relative to one another in such a way that the optoelectronic component is arranged between the first substrate and the second substrate. A bonding material is arranged between the first substrate and the second substrate, which material encloses the optoelectronic component and bonds the first and second substrates together mechanically. The bonding material comprises silver oxide in a proportion of 20 to 70 wt. % inclusive. The bonding material further includes at least one filler, which changes, preferably reduces, the coefficient of thermal expansion of the bonding material.

The optoelectronic component is preferably completely enclosed by the first substrate, the second substrate and the bonding material. The two substrates and the bonding material here preferably form a closed cell, in which the optoelectronic component is arranged. The cell is here composed of two bases, in particular the first substrate and the second substrate, and side faces, in particular the bonding material, the side faces bonding the two bases together.

A distance is preferably arranged between the bonding material and the optoelectronic component. The bonding material is particularly preferably arranged adjacent the optoelectronic component on the first substrate, the bonding material being spaced laterally from the optoelectronic component. In particular the bonding material is not in contact with the optoelectronic component.

The organic optoelectronic component is protected in particular from environmental influences particularly preferably by the bonding material, which is arranged between the first and second substrates in such a way that the bonding material constitutes a mechanical bond between first substrate and second substrate.

Environmental influences should be understood in particular to mean the penetration of air and/or moisture into the unit. The penetration of air or moisture into the unit would lead to damage to or even destruction of the organic optoelectronic component.

A consequence of excluding water vapour, oxygen and moisture is an advantageously increased service life of the optoelectronic component. In addition, the amount of getter is advantageously reduced or dispensed with entirely. This advantageously gives rise to a unit which may be more simply and less expensively produced.

Air-tight enclosure preferably proceeds by means of the bonding material, which contains silver oxide in a proportion of more than 0 wt. % and less than 100 wt. %, preferably of between 5 wt. % and 80 wt. % inclusive, ideally of between 10 wt. % and 70 wt. % inclusive, and at least one filler, which changes, preferably reduces, the coefficient of thermal expansion of the bonding material.

Glass solders which comprise silver oxide in a proportion of between 20 to 70 wt. % and the production thereof are described for example in patents DE 4 128 804 A1 and DE 2 222 771 A1, whose disclosure content is hereby explicitly included in the description by reference.

In a preferred configuration the bonding material comprises silver oxide in a proportion of more than 0 wt. % and less than 100 wt. %, preferably between 5 wt. % and 80 wt. %

inclusive, ideally between 10 wt. % and 70 wt. % inclusive.

In a further preferred configuration the bonding material comprises a lead-free glass. Particularly preferably the bonding material is a lead-free glass.

In a further preferred configuration the bonding material comprises a low melting point glass. Preferably the bonding material is a low melting point glass.

Particularly preferably the bonding material is a lead-free and low melting point glass.

A low melting point glass is in particular a glass which has a very low softening point for stoving temperatures of below 600° C., preferably below 500° C., particularly preferably below 400° C., ideally below 350° C.

In a preferred embodiment the bonding material comprises a glass frit. A glass frit is in particular an intermediate in the production of glass melts. The glass frit arises as a result of superficial melting of glass powder, the glass grains fusing together. The glass frit consists in particular of a porous material.

In a further embodiment the bonding material comprises a glass solder. A glass solder for encapsulating a unit is known for example from document U.S. Pat. No. 6,936,963 B2, whose disclosure content is hereby explicitly included by reference.

In a further preferred further development of the unit, the filler has a negative coefficient of thermal expansion. Examples of suitable fillers are described for example in the article “Festkörper mit negativer thermischer Ausdehnung” [“Solids with negative thermal expansion”] by Ch. Georgi and H. Kern, Ilmenau University of Technology, Institute for Materials Technology, whose disclosure content is hereby explicitly included by reference. In particular, the disclosure content of table 1 on page 4 thereof is hereby explicitly included by reference.

In a preferred embodiment the proportion of the filler in the bonding material is below 50 vol. %, preferably below 30 vol. %.

In a preferred further development of the unit the bonding material contains at least one ingredient and/or one further filler which absorbs radiation. The ingredient and/or the further filler preferably at least partially absorb infrared and/or ultraviolet radiation. Preferably the bonding material with the ingredient contained therein and/or the further filler absorbs 20% of infrared and/or ultraviolet radiation, preferably 40%, particularly preferably 60% or more.

A bonding material which inter alia comprises further fillers with absorbent characteristics in the wavelength range of infrared or ultraviolet radiation advantageously exhibits heat-insulating characteristics. In addition, a bonding material which is absorbent in the stated wavelength range protects the organic optoelectronic component from sunlight.

The further filler may in this case in particular be a radiation-absorbing element or a compound. For example, the filler is vanadium oxide, a spinel or a spinel compound.

A spinel is in particular a magnesium aluminium oxide mineral with the chemical formula MgAl₂O₄ which crystallises in the cubic crystal system. Spinel compounds are additionally suitable as further fillers exhibiting absorbent characteristics. Spinel compounds have a similar crystal structure to spinel and are inter alia chemical compounds of the general type AP₂X₄, A being a divalent metal cation, P a trivalent metal cation and X predominantly an oxide or sulfide. Examples of spinel compounds are inter alia magnesium spinels (MgAl₂O₄), gahnites (ZnAl₂O₄) or cobalt spinels (CoAl₂O₄) (cobalt aluminate).

The further filler may for example be a constituent of the bonding material itself. Alternatively, the further filler may be subsequently admixed with the bonding material.

In a preferred embodiment the first substrate and/or the second substrate is in each case a glass substrate.

Particularly preferably, the first substrate and/or the second substrate consist of window glass.

Window glass should in particular be taken to mean a calcareous, sodium-containing glass, which contains calcium carbonate for example. Further carbonates and/or oxides and contamination may additionally be contained in the window glass. Such a glass is also known as soda-lime glass.

Window glass is an inexpensive material compared with borosilicate glass. A unit comprising a first substrate and a second substrate of window glass may thus be inexpensively produced.

The optoelectronic component is preferably an organic light- emitting diode (OLED). The optoelectronic component may furthermore be an organic photodiode or an organic solar cell.

Organic components, in particular OLEDs, are particularly susceptible to environmental influences such as for example water vapour or oxygen. Sealing of the unit against water vapour and oxygen by means of the bonding material is therefore particularly advantageous, in particular in relation to OLEDs.

In a preferred embodiment of the unit, the unit comprises a first substrate and a second substrate, at least one optoelectronic component being arranged on the first substrate, which component contains at least one organic material. The first substrate and the second substrate are arranged relative to one another in such a way that the optoelectronic component is arranged between the first substrate and the second substrate. A bonding material is arranged between the first substrate and the second substrate, which material surrounds the optoelectronic component and bonds the first and second substrates together mechanically. The bonding material includes silver oxide in a proportion of more than 0 wt. % and less than 100 wt. %, preferably of between 5 wt. % and 80 wt. % inclusive, ideally of between 10 wt. % and 70 wt. % inclusive, and optionally a filler, which changes, preferably reduces, the coefficient of thermal expansion of the bonding material. The bonding material is a lead-free low melting point glass and contains at least one ingredient and/or one further filler which absorbs radiation, such as for example vanadium oxide, a spinel or a spinel compound. Optionally the bonding material additionally contains a further filler which preferably has a negative coefficient of thermal expansion. The proportion of the filler in the bonding material is below 50 vol. %, preferably below 30 vol. %.

Such low melting point, silver oxide-containing bonding materials optionally with a filler for reducing the coefficient of thermal expansion allow oxygen- and water vapour-tight sealing of the unit in particular at low temperatures. A consequence of excluding water vapour and oxygen is an advantageously lengthened service life of the organic optoelectronic component. In addition, the amount of getter is advantageously reduced or dispensed with entirely. This advantageously reduces production costs.

A method of producing a unit comprising a first substrate, a second substrate, an optoelectronic component and a bonding material, comprises the following method steps:
providing a first substrate, on which at least one optoelectronic component is arranged, which component contains at least one organic material,
providing a second substrate,
arranging a bonding material on the first or second substrate, the bonding material containing silver oxide in a proportion of more than 0 wt. % and less than 100 wt. %, preferably between 5 and 80 wt. % inclusive, ideally between 10 wt. % and 70 wt. % inclusive, optionally with a filler introduced therein which changes, preferably reduces, the coefficient of thermal expansion of the bonding material,
arranging the first substrate and the second substrate relative to one another in such a way that the optoelectronic component and the bonding material are arranged between the first substrate and the second substrate, the bonding material enclosing the optoelectronic component, and
fusing the bonding material, such that the first substrate and the second substrate are bonded together mechanically.

The bonding material may here be arranged on the second substrate. In this case the first substrate and the second substrate are then arranged relative to one another in such a way that the bonding material encloses the optoelectronic component.

Alternatively the bonding material may be arranged on the first substrate, the bonding material then being applied in such a way that the optoelectronic component is enclosed by the bonding material. The optoelectronic component is preferably applied to the first substrate after the bonding material. In this case the second substrate is then arranged relative to the first substrate in such a way that the optoelectronic component and the bonding material are arranged between the first and second substrates.

Advantageous configurations of the method are obtained analogously to the advantageous configurations of the unit and vice versa. A unit described herein may in particular be produced by means of the method. This means that the features disclosed in relation to the unit are also disclosed for the method.

Such a method may be used to produce a unit which comprises an organic optoelectronic component, the organic optoelectronic component being protected against environmental influences, such as for example moisture or air, by sealing the unit. The unit is in this case advantageously inexpensive to produce, since the special composition of the bonding material, in particular the high proportion of silver oxide and the filler for reducing the coefficient of thermal expansion, reduces, in particular advantageously completely dispenses with, the required amount of getter.

The bonding material preferably has a pasty consistency for application to one of the substrates, such that the bonding material may be applied in such a way, starting at a point, preferably without interruption, that it forms a closed frame. After application of the bonding material, the latter is preferably sintered together with the substrate to which it has been applied.

Alternatively the bonding material comprises a powdery consistency and is trickled onto one of the substrates.

Temperatures of less than 400° C. are preferably used for fusing the bonding material. In particular, a bonding material composition is used which allows fusing at temperatures of less than 400° C. The bonding material preferably produces good adhesion at firing temperatures of for example 330° C. and below, whereby an oxygen- and water vapour-tight seal may advantageously be achieved even at such firing temperatures.

In a preferred configuration fusing of the bonding material proceeds locally by a rotary radiation source, for example a laser beam. To this end, the bonding material is temporarily softened locally by means of a laser beam and then hardened by cooling.

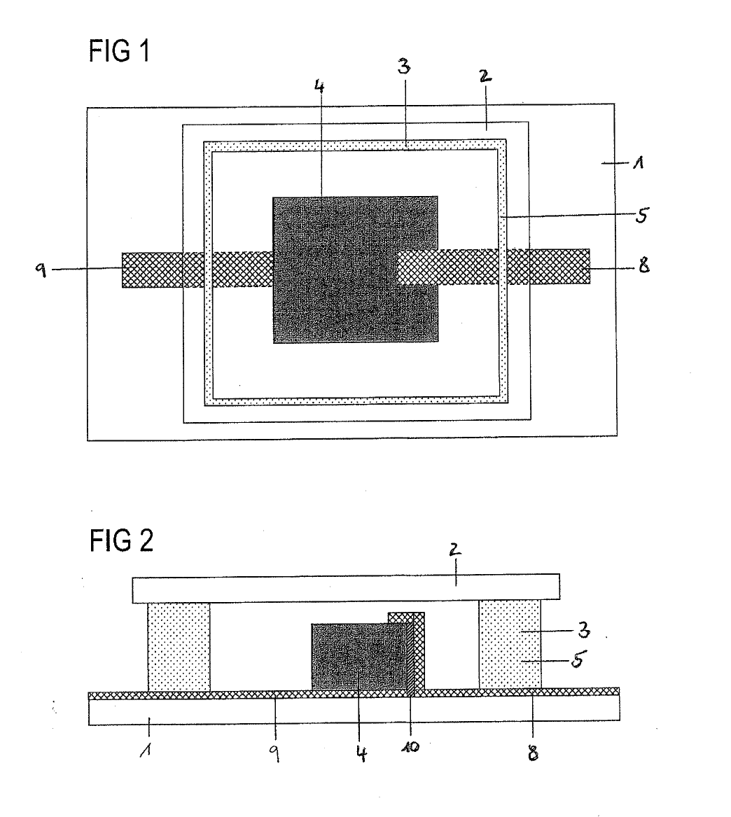

Further features, advantages, preferred configurations and convenient aspects of the unit and of the production method are revealed by the exemplary embodiments explained below with reference to FIGS. 1 to 4, in which:

FIGS. 1, 2 and 3 each show schematic representations of an exemplary embodiment of a unit according to the invention, and

FIG. 4 shows a schematic cross-section of an organic light-emitting diode (OLED).

Identical or equivalently acting components are in each case denoted with identical reference numerals. The components illustrated and the size ratios of the components to one another should not be regarded as to scale.

FIG. 1 shows a schematic plan view of a unit. FIG. 2 represents a schematic cross-section of a unit according to the invention, for example a schematic cross-section of the unit of FIG. 1. The unit comprises a first substrate 1 and a second substrate 2. An optoelectronic component 4 is arranged between the first substrate 1 and the second substrate 2. The optoelectronic component 4 contains at least one organic material.

The optoelectronic component 4 is preferably a radiation- emitting component, particularly preferably an organic light- emitting diode (OLED). An OLED is distinguished in that at least one layer of the OLED includes an organic material. An OLED comprises the following structure, for example, which is illustrated inter alia in FIG. 4: cathode 47, electron-inducing layer 46, electron-conducting layer 45, emitting layers 44, hole-conducting layer 43, hole- inducing layer 42 and anode 41.

One of the layers, preferably all of the layers except the cathode and the anode, comprises an organic material.

The optoelectronic component 4 may furthermore be a photodiode or a solar cell, which contains at least one organic material.

A bonding material 3 is arranged between the first substrate 1 and the second substrate 2. The bonding material 3 preferably encloses the optoelectronic component 4 in the manner of a frame. The bonding material 3 additionally bonds the first substrate 1 and the second substrate 2 together mechanically.

The bonding material 3 preferably completely encloses the optoelectronic component 4.

The bonding material 3 preferably includes silver oxide in a proportion of more than 0 wt. % and less than 100 wt. %, preferably between 5 wt. % and 80 wt. % inclusive, ideally between 10 wt. % and 70 wt. % inclusive. The bonding material 3 particularly preferably comprises silver oxide in a proportion of 50 to 70 wt. % inclusive.

The bonding material further includes at least one filler 5, which changes, preferably reduces, the coefficient of thermal expansion of the bonding material 3. The filler 5 preferably has a negative coefficient of thermal expansion. The proportion of filler 5 in the bonding material 3 is preferably below 50 vol. %, particularly preferably below 30 vol. %. By means of the filler 5 the coefficient of thermal expansion of the bonding material 3 may in particular advantageously be adapted in such a way that improved oxygen- and water vapour-tight sealing of the organic optoelectronic component 4 may be achieved. Permanently tight sealing of the unit may in particular be achieved in this way.

Such a composition of the bonding material 3 and the complete enclosure of the optoelectronic component 4 by means of the bonding material 3 allow the bonding material 3 advantageously to protect the optoelectronic component 4 from environmental influences. Environmental influences should be understood in particular to mean the penetration of air or moisture into the unit. Specifically in the case of optoelectronic components 4 which comprise at least one organic layer, contact with air or moisture disadvantageously leads to damage or even destruction of the organic optoelectronic component 4. This may advantageously be prevented by the special composition of the bonding material 3.

Air-tight enclosure of the unit by the bonding material 3 thus advantageously increases the service life of the organic optoelectronic component 4 significantly.

In addition, production of the unit is simplified, since a getter material introduced into a cavity in one of the substrates 1, 2 is not necessary due to the special composition of the bonding material 3. The quantity of getter required is thereby reduced or dispensed with entirely. In addition, machining of one of the substrates, in particular the formation of a cavity and the introduction of a getter, is advantageously unnecessary. Such units can advantageously be produced inexpensively.

The first substrate 1 and/or the second substrate 2 is/are preferably each a glass substrate. Particularly preferably, the first substrate 1 and/or the second substrate 2 contain window glass. Window glass represents an inexpensive material compared to other glass materials, such as for example borosilicate glass. A unit which comprises a first substrate 1 and a second substrate 2 of window glass is thus advantageously inexpensive to produce.

The bonding material 3 preferably comprises a glass frit. Alternatively, the bonding material 3 may comprise a glass solder. In particular, the bonding material 3 is preferably a lead-free and/or low melting point glass.

Preferably the first substrate 1 projects laterally beyond the second substrate 2 when the second substrate 2 is viewed in plan view, as shown in FIG. 1. This means that the first substrate 1 and the second substrate 2 have bases of different sizes, the first substrate 1 preferably having a larger base than the second substrate 2.

Electrical feed 8, 9 to the organic optoelectronic component 4 preferably takes place on the surface of the first substrate 1 facing the optoelectronic component 4. One of the electrical feeds 8, 9 is guided from a contact of the optoelectronic component 4, which is located on the side of the optoelectronic component 4 remote from the first substrate 1, over a side face of the optoelectronic component 4 to the first substrate 1. The guide path along the side face of the optoelectronic component 4 is here electrically insulated from the layers of the optoelectronic component 4 by an electrically insulating layer 10.

Electrical contacting of the optoelectronic component 4 is illustrated schematically in particular in FIG. 2.

Because the first substrate 1 preferably has a larger base than the second substrate 2, the electrical feeds 8, 9 of the optoelectronic component 4 may be guided out of the bonding material 3 and connected electrically there. The electrical feeds 8, 9 of the optoelectronic component 4 in particular project laterally beyond the second substrate 2, such that the electrical feeds 8, 9 may be electrically connected without difficulty.

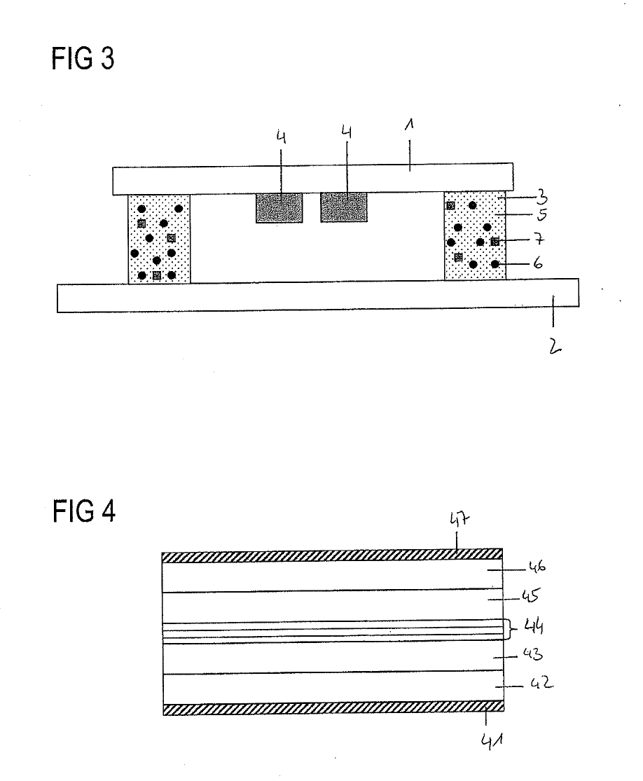

The unit illustrated in FIG. 3 differs from the unit illustrated in FIG. 2 in that a plurality of organic optoelectronic components 4 are arranged between the first substrate 1 and the second substrate 2. The unit is accordingly not limited to the use of just one optoelectronic component 4. The number of organic optoelectronic components 4 may vary in the light of the purpose for which the unit is to be used.

In addition, unlike with the unit of FIG. 2 the bonding material 3 contains a further filler 6, which absorbs radiation. Particularly preferably, the further filler 6 absorbs radiation in the infrared and/or ultraviolet wavelength range. It is thus advantageously possible to prevent exposure to sunlight, which may disadvantageously damage the optoelectronic component 4.

For example, the further filler 6 is vanadium oxide, a spinel or a spinel compound.

A further difference between the unit of FIG. 3 and the unit of FIG. 2 is that the bonding material 3 contains a further substance 7 which serves as a spacer to space the first substrate 1 and the second substrate 2 from one another. Alternatively, a spacer may be integrated in the unit which is arranged not in the bonding material 3 but instead (not shown) between optoelectronic component 4 and bonding material 3.

Spacers 7 serve to purposefully establish a fixed distance between first substrate 1 and second substrate 2. In this way the substrates 1, 2 may be prevented from moving closer together than the distance established by the spacers 7 during the process of softening the bonding material 3, such that the organic optoelectronic components 4 are not damaged during the production process by too small a distance between the first substrate 1 and the second substrate 2.

The bonding material 3 is preferably softened using temperatures of less than 400° C.

For example, a method of producing a unit according to FIG. 1, FIG. 2 or FIG. 3 may comprise the following method steps:

A bonding material 3, for example a glass frit, is applied to, for example trickled onto, preferably sintered onto a second substrate 2, for example in the form of a frame. In addition, a first substrate 1 is provided, to which an organic optoelectronic component 4 has been applied.

The bonding material 3 contains silver oxide in a proportion of more than 0 wt. % and less than 100 wt. %, preferably of between 5 wt. % and 80 wt. % inclusive, ideally of between 10 wt. % and 70 wt. % inclusive, and at least one filler 5, which changes, preferably reduces, the coefficient of thermal expansion of the bonding material 3. The filler 5 may in this case be directly contained in the bonding material 3 or admixed subsequently therewith.

Spacers 7 and further fillers 6, which in particular absorb radiation, are preferably introduced into the bonding material 3.

The first substrate 1 is then placed onto the second substrate 2. The first substrate 1 is placed onto the second substrate 2 in such a way that the organic optoelectronic component 4 is arranged between first substrate 1 and second substrate 2. In addition, the first substrate 1 and the second substrate 2 are arranged relative to one another in such a way that the bonding material 3 surrounds the organic optoelectronic component 4, for example encloses it in the manner of a frame.

The bonding material 3 may then be fused using temperatures of less than 400° C. in such a way that the first substrate 1 and the second substrate 2 are bonded together mechanically.

Through the special composition of the bonding material 3 it is advantageously possible to form a hermetically sealed bond between first substrate 1 and second substrate 2. This advantageously allows oxygen- and water vapour-tight sealing of the OLED, so advantageously lengthening the service life of the unit. In addition, getters and the associated costly machining steps may be avoided. Simplified, inexpensive production of hermetically sealed units is thus advantageously possible.

The invention is not limited to the exemplary embodiments as a result of the description made with reference thereto, but instead the invention encompasses any novel feature and any combination of features, including in particular any combination of features in the claims, even if this feature or this combination is not itself explicitly indicated in the claims or exemplary embodiments.

1. A unit comprising a first substrate and a second substrate, comprising:
at least one optoelectronic component containing at least one organic material is arranged on the first substrate;
wherein the first substrate and the second substrate are arranged relative to one another such that the optoelectronic component is arranged between the first substrate and the second substrate;
a bonding material is arranged between the first substrate and the second substrate, which encloses the optoelectronic component and bonds the first and second substrates together mechanically;
wherein the bonding material comprises silver oxide in a proportion of 20 to 70 wt. % inclusive; and
wherein the bonding material includes at least one filler, which changes the coefficient of thermal expansion of the bonding material.

2. The unit according to claim 1, wherein the bonding material comprises a lead-free and/or low melting point glass.

3. The unit according to claim 1, wherein the bonding material is a glass frit or a glass solder.

4. The unit according to claim 1, wherein the filler has a negative coefficient of thermal expansion.

5. The unit according to claim 1, wherein the proportion of the filler in the bonding material is below 50 vol. %.

6. The unit according to claim 5, wherein the proportion of filler in the bonding material is below 30 vol. %.

7. The unit according to claim 1, wherein the bonding material contains at least one ingredient and/or one further filler which absorbs radiation.

8. The unit according to claim 7, wherein the ingredient and/or the further filler is vanadium oxide, a spinel or a spinel compound.

9. The unit according to claim 1, wherein the bonding material contains at least one further substance, which serves as a spacer to space the first and second substrates from one another.

10. The unit according to claim 1, wherein the first substrate and/or the second substrate is/are a glass substrate.

11. The unit according to claim 1, wherein the optoelectronic component (4) is an organic light-emitting diode.

12. The unit according to claim 1, wherein
the bonding material is a lead-free and low melting point glass,
the filler has a negative coefficient of thermal expansion,
the proportion of filler in the bonding material is below 30 wt. %,
the bonding material contains at least one ingredient and/or one further filler which absorbs radiation, and
the further filler is vanadium oxide or a spinel.

13. A method of producing a unit, comprising the steps of:
providing a first substrate, on which at least one optoelectronic component is arranged, which component contains at least one organic material;
providing a second substrate;
arranging a bonding material on the first or second substrate, wherein the bonding material comprises silver oxide in a proportion of 20 to 70 wt. % inclusive, and at least one filler is introduced into the bonding material, which filler changes the coefficient of thermal expansion of the bonding material;
arranging the first substrate and the second substrate relative to one another in such a way that the optoelectronic component and the bonding material are arranged between the first substrate and the second substrate, the bonding material enclosing the optoelectronic component; and
fusing the bonding material, such that the first substrate and the second substrate are joined together mechanically.

14. (canceled)

15. The method according to claim 13, wherein temperatures of less than 400° C. are used for fusing.

16. The method according to claim 13, wherein said filler reduces the coefficient of thermal expansion of the bonding material.

17. The unit according to claim 1, wherein said filler reduces the coefficient of thermal expansion of the bonding material.
